(19) United States
(12) Patent Application Publication
(10) Pub. No.: US 2016/0375515 A1
(43) Pub. Date: Dec. 29, 2016

(54) USE OF ATOMIC LAYER DEPOSITION COATINGS TO PROTECT BRAZING LINE AGAINST CORROSION, EROSION, AND ARCING

(71) Applicant: Lam Research Corporation, Fremont, CA (US)

(72) Inventors: Lin XU, Katy, TX (US); John DAUGHERTY, Fremont, CA (US); Hong SHIH, Walnut, CA (US); Yiwei SONG, Union City, CA (US); Satish SRINIVASAN, Newark, CA (US)

(21) Appl. No.: 14/754,441

(22) Filed: Jun. 29, 2015

(51) Int. Cl. B23K 1/00; B32B 15/01; C23C 16/455; H01J 37/32; B23K 31/02; C25D 11/04

(52) U.S. Cl. CPC B23K 1/0008; B23K 31/02; C25D 11/04; C23C 16/45525; H01J 37/32431; B32B 15/016; H01J 2237/334

(57) ABSTRACT

In accordance with this disclosure, there are provided several inventions, including an apparatus and method for brazing at least two aluminum or aluminum alloy components and providing an anodized coating, and an atomic layer deposition coating for adding plasma corrosion resistance.

### BACKGROUND

This disclosure relates to the brazing and/or coating of components in etch chambers used in semiconductor processing.

In plasma processing chambers, components sometimes need to be joined together. Existing methods of joining components may result in joints that contain contaminants. In addition, the joint may have poor corrosion resistance. New ways are therefore needed to join components in plasma chambers.

### SUMMARY

Among other things, disclosed herein are methods for making a plasma chamber component. This method may include any or all of the following steps: providing first and second components made of aluminum or aluminum alloy; brazing the first and second components using a mixture of aluminum and silicon, to form a brazing interface; anodizing at least a portion of the first and second components, such that an anodized coating forms over the brazing interface; and conformally coating the anodized coating using atomic layer deposition, to form an ALD coating.

In various further embodiments of the above methods, the ALD coating may be a corrosion-resistant dielectric material. The ALD coating may be a plasma corrosion resistant oxide comprising yttrium, zirconium, and/or aluminum. The ALD coating may be alumina. The mixture of aluminum and silicon may be an approximately eutectic mixture comprising 5-20% silicon. The brazing may be performed at a temperature less than about 120° C. The first component may be a fluid distribution plate may include one or more open channels for distributing a fluid; in one embodiment, the step of brazing may cause the open channels to be at least partially enclosed by at least a portion of the second component. Further, The second component may comprise one or more fluid passages through the second component; the fluid passages may have a first end and a second end. In addition, the step of brazing may connect each first end to at least one of the channels for fluid communication between them. In another embodiment, the plasma chamber component may be an electrostatic chuck.

Also disclosed are embodiments of a plasma processing chamber. This chamber may include a first and a second component made of aluminum or aluminum alloy. It may include a brazing interface between the first and second components comprising a mixture of aluminum and silicon. It may include an anodized coating covering at least the brazing interface, such that the brazing interface is not exposed to the exterior of the part. It may further include a conformal ALD coating deposited by atomic layer deposition over the anodized coating.

In various further embodiments of the above plasma processing chambers, the first component may be a fluid distribution plate comprising one or more channels for distributing a fluid; at least a portion of the channels may be at least partially enclosed by at least a portion of the second component. The second component may comprise one or more fluid passages through the second component; the fluid passages may have a first end and a second end; each first end may open into at least one of the channels for fluid communication between them. In further embodiments, the ALD coating may be a corrosion resistant dielectric material. The ALD coating may be a plasma corrosion resistant oxide comprising yttrium, zirconium, and/or aluminum. The ALD coating is alumina. The mixture of aluminum and silicon is an approximately eutectic mixture comprising 5-20% silicon. The “part” mentioned above may be an electrostatic chuck.

These and other features of the present inventions will be described in more detail below in the detailed description and in conjunction with the following figures.

### BRIEF DESCRIPTION OF THE DRAWINGS

The disclosed inventions are illustrated by way of example, and not by way of limitation, in the figures of the accompanying drawings and in which like reference numerals refer to similar elements and in which:

FIGS. 1A and 1B are schematic cross-sectional views of an example electrostatic chuck before and after brazing, respectively.

FIGS. 2A and 2B are schematic cross-sectional views of an example gas distribution system before and after brazing, respectively.

### DETAILED DESCRIPTION

Inventions will now be described in detail with reference to a few of the embodiments thereof as illustrated in the accompanying drawings. In the following description, specific details are set forth in order to provide a thorough understanding of the present invention. However, the present invention may be practiced without some or all of these specific details, and the disclosure encompasses modifications which may be made in accordance with the knowledge generally available within this field of technology. Well-known process steps and/or structures have not been described in detail in order to not unnecessarily obscure the present disclosure.

It is often useful to create a hermetical joint between plasma processing chamber components of aluminum alloys to, for example, create a cavity for gas or fluid delivery. In one embodiment, a method of creating such a joint is vacuum brazing. In one embodiment, high-silicon-containing aluminum alloys may be used as a brazing foil. For example, the foil may comprise Al 4047 alloy with approximately 12% silicon, which is near eutectic composition. The silicon concentration can range over a margin that would include about 5-20%, or 10-15%. Other components may also be used, such as magnesium, which in some embodiments may act as a getter, especially when the brazing is done at temperatures higher than about 570° C. Preferably, the brazing composition is eutectic or near eutectic such that when the mixture melts, the solid and liquid compositions are approximately the same, and the melting point is lower than the melting point of the individual components. The lower melting point makes it possible to perform the brazing at lower temperatures. Mixtures with high flowability are preferred, to make a more uniform and conforming brazing joint.

Although a vacuum braze containing silicon can offer a solid structural joint, it could cause issues due to the silicon content. One problem is that when such a brazing joint containing silicon is anozided, the quality of the anodization may be very poor due to a silicon micromasking effect in anodization. This may compromise corrosion resistance at the braze line, especially when the braze line is near highly corrosive gasses such as chlorine, hydrogen bromide, or boron trichloride in dielectric etch chambers. This silicon-rich braze line, when exposed to plasma (for example, the exterior surfaces of braze line at the edge of an electrostatic chuck or gas distribution plate, may cause other issues. For example, fluorine radicals from the plasma may preferentially etch the silicon-rich phase away, degrading the structural soundness of the joint, causing flaking, or possibly creating a high chance of arcing or lightup.

In one embodiment, a brazing line may be protected using dense, super conformal, corrosion resistant atomic layer deposition (ALD) oxide coatings. In one embodiment, such a coating may be formed over an anodized aluminum layer. The ALD coating can be deposited even at low temperature (for example, below about 120° C. or even at room temperature of 20 or 30° C.). In this embodiment, thermal cracking of anodization on the surfaces other than the braze line (e.g., the Al 6061) can be avoided. Further, an ALD coating can penetrate into tortuous geometries, which can enable full protection of a braze line, which may have hidden features, such as internal gas channels.

Some features of an ALD coating may include operation at low temperatures, so as to avoid risk of cracking an anodization layer during coating. Therefore, ALD coating may be compatible with an anodization process. In addition, ALD may form deposits that are free of pinholes or pores, which provides a superior barrier against corrosive gasses and plasma species. ALD coatings are also typically very pure, and may be created without detectable metal impurities other than, perhaps, aluminum from coating. Carbon impurities may also be kept low. ALD coatings are also super-conformal, and uniform in their coating thickness, as well as aspect ratio independent. Coatings can therefore avoid undesirable alterations in the dimensions of the coated part.

Example ALD coating materials may include ceramics, dielectric materials, alumina, zirconia, yttria, combinations of aluminum, zirconium, yttrium, and/or oxygen such as YAG or YSZ, materials with corrosion-resistance, and materials known in the art to have superior resistance to radicals. The material may in several embodiments also be metal oxide, nitride, fluoride, or carbide, or combinations thereof.

Methods of ALD coating are known in the art. See, e.g., U.S. Patent Pub. No. 2014/0113457 A1 (published Apr. 24, 2014), incorporated herein by reference in its entirety. They use surface-mediated deposition reactions to deposit films on a layer-by-layer basis. In one example ALD process, a substrate surface, including a population of surface active sites, is exposed to a gas phase distribution of a first film precursor (P1). Some molecules of P1 may form a condensed phase atop the substrate surface, including chemisorbed species and physisorbed molecules of P1. The reactor is then evacuated to remove gas phase and physisorbed P1 so that only chemisorbed species remain. A second film precursor (P2) is then introduced to the reactor so that some molecules of P2 adsorb to the substrate surface. The reactor may again be evacuated, this time to remove unbound P2. Subsequently, thermal energy provided to the substrate activates surface reactions between adsorbed molecules of P1 and P2, forming a film layer. Finally, the reactor is evacuated to remove reaction by-products and possibly unreacted P1 and P2, ending the ALD cycle. Additional ALD cycles may be included to build film thickness.

### EXAMPLES

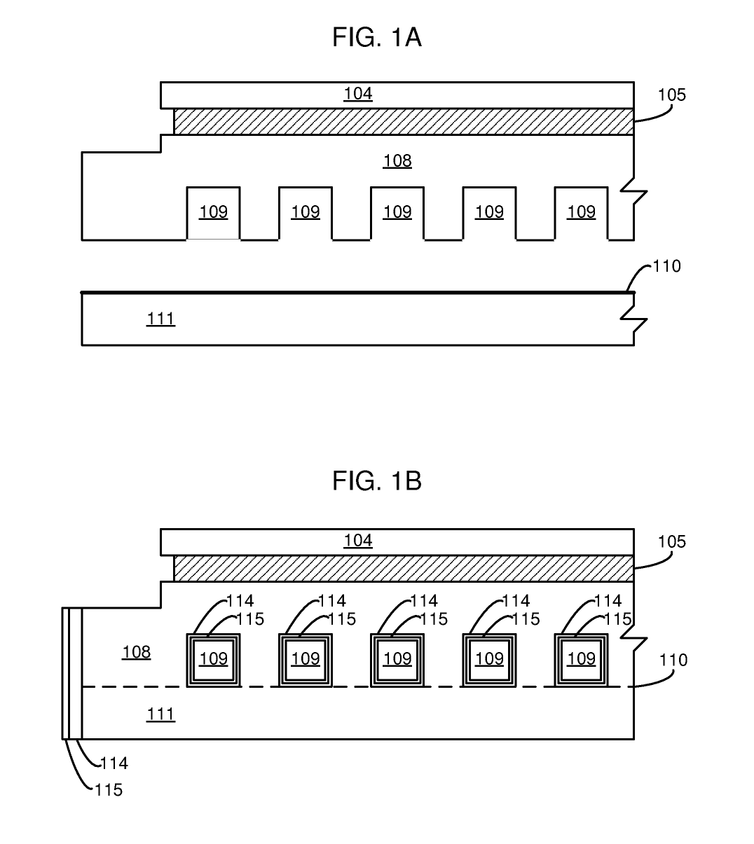

FIG. 1A is a schematic cross-sectional view illustrating one embodiment of an electrostatic chuck containing fluid distribution channels. A ceramic plate 104 may be bonded to a base plate 108 comprising aluminum or an aluminum alloy (such as Al 6061). The bonding may in one example be via a polymer adhesive 105. The base plate 108 may contain channels 109 for gas or liquid flow. These channels may, for example, be formed in complex distribution channels in order to cool or heat the electrostatic chuck. In a separate component 111, also comprising aluminum or an aluminum alloy in this example, a brazing foil 110 may be positioned on one side of the component.

The components 108 and 111 may be joined by brazing, via the brazing foil 110, as illustrated in FIG. 1B, which may comprise a eutectic or near-eutectic mixture of aluminum and silicon. The components may be anodized (preferably after the brazing), such that an anodized layer 114 forms covering at least part of the brazing interface. Anodization may be performed using current in a sulfuric acid bath. Next, a conformal ALD coating 115 may be formed over the anodized, joined components, by atomic layer deposition means known in the art.

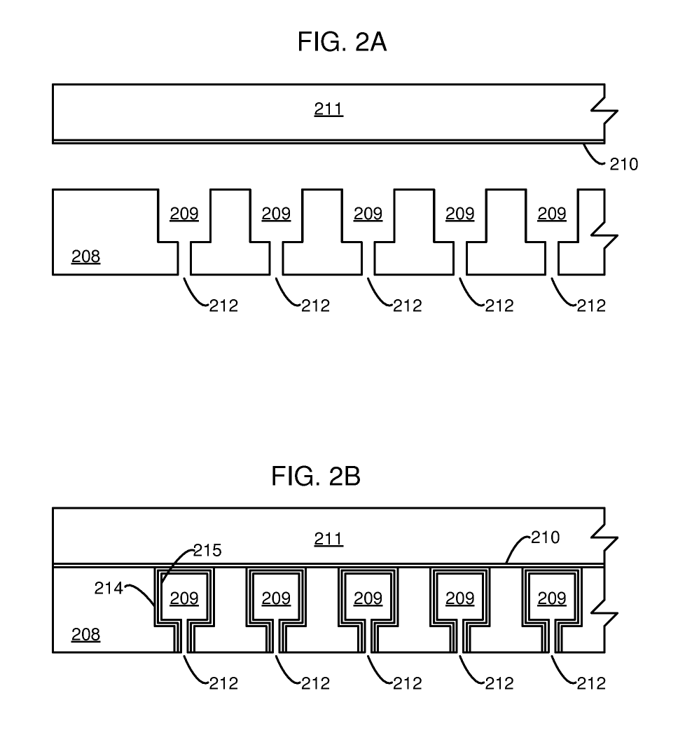

In another embodiment, FIG. 2A is a schematic cross-sectional view illustrating a gas distribution plate, containing channels for distributing gas through a showerhead into a plasma chamber. A plate 208 may comprise aluminum or an aluminum alloy (such as Al 6061), and may contain channels 209 for gas flow. These channels may, for example, be formed in complex distribution channels in order to distribute various gasses to the interior of a plasma processing chamber. In this example there is a separate top plate 211, which may also comprise aluminum or an aluminum alloy (such as Al 6061). In one embodiment, component 208 may be a thermal control plate, which may be joined to a showerhead electrode (not shown) via channels 212. The showerhead electrode may in one embodiment comprise silicon in various forms, including single crystal silicon, polysilicon, silicon nitride, or silicon carbide. Examples of such an electrode may be found in U.S. Pat. No. 8,268,117, which is incorporated herein by reference in its entirety. On top plate 211, a brazing foil 210 may be positioned on the side facing the plate 208. Plate 208 may in one embodiment contain fluid channels 212 designed to carry fluid from the channels 209 to a showerhead electrode.

The components 208 and 211 may be joined by brazing, via the brazing foil 210, as illustrated in FIG. 2B, which may comprise a eutectic or near-eutectic mixture of aluminum and silicon. The components may be anodized (preferably after the brazing), such that an anodized layer 214 forms, covering at least part of the brazing interface. Anodization may be performed using current in a sulfuric acid bath. However, anodization over the brazing foil may in many cases be of poor quality. Next, a conformal ALD coating 215 may be formed over the anodized, joined components, by atomic layer deposition means known in the art.

While inventions have been described in terms of several preferred embodiments, there are alterations, permutations, and various substitute equivalents, which fall within the scope of this invention. There are many alternative ways of implementing the methods and apparatuses disclosed herein. It is therefore intended that the following appended claims be interpreted as including all such alterations, permutations, and various substitute equivalents as fall within the true spirit and scope of the present invention.

What is claimed is:

1. A method for making a plasma chamber component, comprising:
providing first and second components made of aluminum or aluminum alloy;
brazing the first and second components using a mixture of aluminum and silicon, to form a brazing interface;
anodizing at least a portion of the first and second components, such that an anodized coating forms over the brazing interface; and
conformally coating the anodized coating using atomic layer deposition, to form an ALD coating.

2. The method of claim 1, wherein the ALD coating is a corrosion-resistant dielectric material.

3. The method of claim 1, wherein the ALD coating is a plasma corrosion resistant oxide comprising yttrium, zirconium, and/or aluminum.

4. The method of claim 3, wherein the ALD coating is alumina.

5. The method of claim 1, wherein the mixture of aluminum and silicon is an approximately eutectic mixture comprising 5-20% silicon.

6. The method of claim 1, wherein the brazing is performed at a temperature less than about 120° C.

7. The method of claim 1, wherein the first component is a fluid distribution plate comprising one or more open channels for distributing a fluid, and wherein the step of brazing causes the open channels to be at least partially enclosed by at least a portion of the second component.

8. The method of claim 7, wherein the second component comprises one or more fluid passages through the second component, the fluid passages having a first end and a second end, and wherein the step of brazing connects each first end to at least one of the channels for fluid communication between them.

9. The method of claim 1, wherein the plasma chamber component is an electrostatic chuck.

10. A part for a plasma processing chamber, comprising:
a first and a second component made of aluminum or aluminum alloy;
a brazing interface between the first and second components comprising a mixture of aluminum and silicon;
an anodized coating covering at least the brazing interface, such that the brazing interface is not exposed to the exterior of the part; and
a conformal ALD coating deposited by atomic layer deposition over the anodized coating.

11. The part of claim 10, wherein the first component is a fluid distribution plate comprising one or more channels for distributing a fluid, and wherein at least a portion of the channels is at least partially enclosed by at least a portion of the second component.

12. The part of claim 11, wherein the second component comprises one or more fluid passages through the second component, the fluid passages having a first end and a second end, and wherein each first end opens into at least one of the channels for fluid communication between them.

13. The part of claim 10, wherein the ALD coating is a corrosion resistant dielectric material.

14. The part of claim 10, wherein the ALD coating is a plasma corrosion resistant oxide comprising yttrium, zirconium, and/or aluminum.

15. The part of claim 14, wherein the ALD coating is alumina.

16. The part of claim 10, wherein the mixture of aluminum and silicon is an approximately eutectic mixture comprising 5-20% silicon.

17. The part of claim 10, wherein the part is an electrostatic chuck.
